(19) United States
(12) Patent Application Publication
(10) Pub. No.: US 2026/0180534 A1
(43) Pub. Date: Jun. 25, 2026

(54) ELECTRONIC AMPLIFIER

(71) Applicant: Renesas Electronics America Inc., Milpitas, CA (US)

(72) Inventors: Domenico PEPE, Zurich (CH); Bortecene TERLEMEZ, Zurich (CH)

(73) Assignee: Renesas Electronics America Inc., Milpitas, CA (US)

(21) Appl. No.: 18/999,220

(22) Filed: Dec. 23, 2024

(51) Int. Cl. H03G 3/30; H03F 3/04

(52) U.S. Cl. CPC H03G 3/30; H03F 3/04; H03F 2200/03; H03G 2201/103

(57) ABSTRACT

A variable gain amplifier has cascode stages formed of pairs of cross-coupled transistors. Each pair of cross-coupled transistors is provided with a transformer which keeps impedances presented to the cross coupled transistors constant with gain.

The present disclosure relates to an electronic amplifier and apparatus containing the electronic amplifier.

### BACKGROUND

A variable gain amplifier is a type of electronic amplifier which adjust its own gain dynamically based on an external control signal. This enables precise control over the amplitude of the output signal of the amplifier. Such electronic amplifiers are used in applications which require a large dynamic range, such as audio processing, communication systems, and signal conditioning.

However, in high-frequency applications, the response of the electronic amplifier is not uniform across different gain settings which results in a non-uniform frequency response across all gains of the electronic amplifier. As the electronic amplifier is part of an electronic system (for example, a receiver or a transmitter), the signal integrity has to be ensured at all conditions. If the frequency response of the electronic amplifier changes across gains, other components in the electronic system, for example equalizers or digital signal processors, whose parameters have been fine tuned to provide signal integrity at a specific gain, will not be capable to ensure proper signal integrity at different gains.

In the context of the present disclosure, an application (that is, implementation context) is said to be “high-frequency” when the electronic amplifier is operating at frequencies higher than hundreds of megahertz, or at several gigahertz or beyond. For example, electronic amplifiers which are used for telecommunications systems (5G, WiFi, Satellite communications), optical systems (datacom, telecom), radar systems, test and equipment, and/or medical systems and others are electronic amplifiers being used in high-frequency applications.

It is an objective of the present disclosure to overcome one or more of the above limitations.

### SUMMARY

According to a first aspect of the disclosure, there is provided an electronic amplifier comprising: a first transistor comprising a first terminal and a second terminal; a second transistor, comprising a third terminal and a fourth terminal; a first pair of cross-coupled transistors comprising a third transistor and a fourth transistor, the first pair of cross-coupled transistors connected to the second terminal; a second pair of cross-coupled transistors the second pair of cross-coupled transistors comprising a fifth transistor and a sixth transistor, the second pair of cross-coupled transistors connected to the fourth terminal, the first and second pair of cross-coupled transistors forming a cascode stage; a first transformer; a second transformer; wherein the first transformer is coupled between the second terminal and the first pair of cross-coupled transistors and the second transformer is coupled between the fourth node and the second pair of cross-coupled transistors, such that the first transformer and the second transformer provide an impedance to the cascode stage, the impedance configured to be substantially constant for different gains when the electronic amplifier is operated with high frequency.

Optionally, the electronic amplifier is a variable gain amplifier.

Optionally, the variable gain amplifier is a gilbert cell, a differential variable gain amplifier and/or a single-ended variable gain amplifier.

Optionally, the first transistor and the second transistor form a first pair of differential transistors.

Optionally, the first transistor and/or the second transistor comprise one of: a bipolar junction transistor, a field-effect transistor (FET), heterojunction bipolar transistor, junction FET, metal-oxide semiconductor FET, insulated gate bipolar transistor, metal semiconductor FET, high electron mobility transistor, Fin FET, or Tunnel FET.

Optionally, one or each of the transistors forming the first pair of cross-coupled transistors and the second pair of cross-coupled transistors comprise one of: a bipolar junction transistor, a field-effect transistor (FET), heterojunction bipolar transistor, junction FET, metal-oxide semiconductor FET, insulated gate bipolar transistor, metal semiconductor FET, high electron mobility transistor, Fin FET, or Tunnel FET.

Optionally, the first transformer comprises a first pair of coupled spiral inductors and the second transformer 220) comprises a second pair of coupled spiral inductors.

Optionally, the first pair of coupled spiral inductors has an orientation configured to generate a first high-frequency impedance.

Optionally, the second pair of coupled spiral inductors has an orientation configured to generate a second high-frequency impedance.

According to a first aspect of the disclosure, there is provided an apparatus comprising an electronic amplifier comprising: a first transistor comprising a first terminal and a second terminal; a second transistor, comprising a third terminal and a fourth terminal; a first pair of cross-coupled transistors comprising a third transistor and a fourth transistor, the first pair of cross-coupled transistors connected to the second terminal; a second pair of cross-coupled transistors the second pair of cross-coupled transistors comprising a fifth transistor and a sixth transistor, the second pair of cross-coupled transistors connected to the fourth terminal, the first and second pair of cross-coupled transistors forming a cascode stage; a first transformer; a second transformer; wherein the first transformer is coupled between the second terminal and the first pair of cross-coupled transistors and the second transformer is coupled between the fourth node and the second pair of cross-coupled transistors, such that the first transformer and the second transformer provide an impedance to the cascode stage, the impedance configured to be substantially constant for different gains when the electronic amplifier is operated with high frequency.

Optionally, the apparatus comprises any of: an audio processing system; a communications system; a signal conditioning system.

### BRIEF DESCRIPTION OF THE DRAWINGS

The disclosure is described in further detail below by way of example only with reference to the accompanying drawings, in which:

FIG. 1 is an example of an electronic amplifier according to the prior art;

FIG. 2 is a first example embodiment of an electronic amplifier according to the present disclosure;

FIG. 3 is an example embodiment of an apparatus comprising the electronic amplifier according to the present disclosure; and

FIG. 4 is an exemplary implementation of an apparatus comprising the electronic amplifier according to the present disclosure.

### DETAILED DESCRIPTION

The most common implementation in the art of a variable gain electronic amplifier is the Gilbert cell. The Gilbert cell is a differential amplifier configuration which utilizes a balanced mixer design to achieve linear, controllable gain variations.

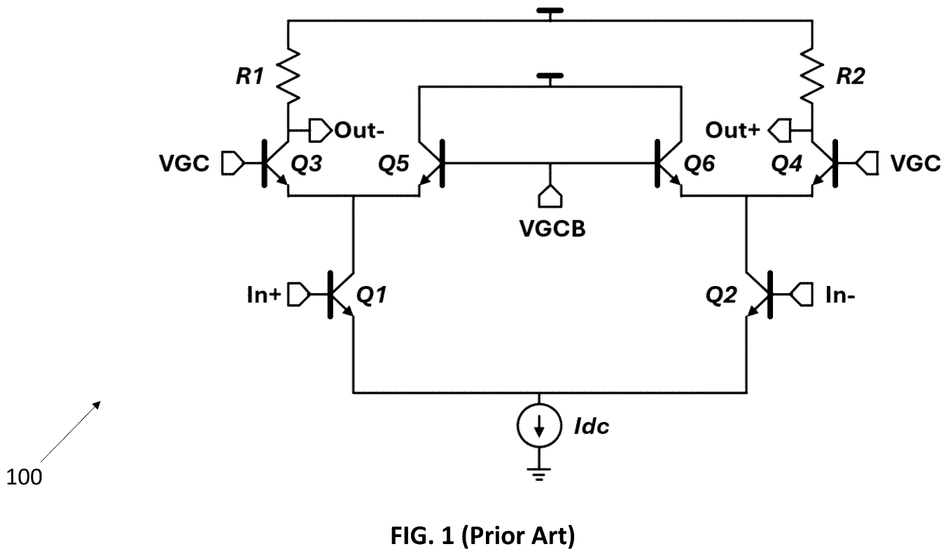

FIG. 1 is an example of a Gilbert cell 100 according to the prior art. The Gilbert cell 100 comprises a pair of differential transistors Q1 and Q2. In this example from the prior art, the pair of differential transistors Q1 and Q2 are bipolar junction transistors which comprise an emitter, base and collector. A positive input signal In+ is fed into the base of bipolar junction transistor Q1 whilst a negative input signal In− is fed into the base of bipolar junction transistor Q2. The emitters of both bipolar junction transistors Q1 and Q2 are connected to a common tail current source Idc.

The Gilbert cell 100 further comprises a first and second pair of cross coupled transistors Q3, Q5 and Q4, Q6 collectively known as the cascode stage. In this example from the prior art, the first and second pair of cross coupled transistors Q3, Q5 and Q4, Q6 are bipolar junction transistors which comprise an emitter, base and collector. The emitters of the first pair of cross coupled transistors Q3, Q5 are coupled to the collector of the bipolar junction transistor Q1 whilst the emitters of the second pair of cross coupled transistors Q4, Q6 are coupled to the collector of the bipolar junction transistor Q2. The collectors of the first and second pair of cross coupled transistors Q3, Q5 and Q4, Q6 are coupled to a load R1 and R2. In alternative embodiments, the load may be a resistor in parallel to a capacitor, an inductor or a selection of these elements in combination.

In operation, the differential current generated by the differential pair of transistors Q1 and Q2 is fed into the first and second pair of cross coupled transistors Q3, Q5 and Q4, Q6. The percentage of current that flows through into the load R1 and R2 is determined by the control voltages VGC and VGCB. The control voltage VGC is input into the bases of bipolar transistors Q3 and Q4, whilst the control voltage VGCB is fed into the bases of bipolar transistors Q5 and Q6. The control voltages VGC and VGCB determine the percentage of the Q1 and Q2 collector currents that will be steered into the load R1 and R2. Hence, the control voltage VGC and VGCB determine the gain of the Gilbert cell 100.

When control voltage VGC is at maximum and control voltage VGCB is at minimum, all the current from the collectors of bipolar junction transistors Q1 and Q2 flows into the load R1 and R2. This is referred to as maximum gain. When control voltage VGC is reduced and control voltage VGCB is increased, part of the current from the collectors of bipolar junction transistors Q1 and Q2 are redirected from the load branches Q3 and Q4 to the dummy branches Q5, resulting in a reduction of the gain of the Gilbert cell 100.

An issue with the Gilbert cell 100 is that during high-frequency applications, the frequency response of the cell 100 is not uniform across different gain settings. This problem is exacerbated between maximum gain and low gain. This is a result of the impedance through the cascode stage varying with gain.

During maximum gain, the impedance towards the emitters of bipolar junction transistors Q3 and Q4 of the cascode stage is given the base-emitter capacitance impedance Cbe of Q3, Q4 in parallel with:

$${R}_{e} = \frac{{V}_{t}}{{I}_{c}}$$

Where Vₜ is the thermal voltage and I_{c} is the current emitted from the collectors of bipolar junction transistors Q1 and Q2. The base-emitter capacitance impedance Cbe is due to the depletion layer modulation and diffusion capacitance and increases when I_{c} increases. At low frequency operation, the impedance towards the emitter of Q3 and Q4 is dominated by Re whilst at high frequency operation it is dominated by Cbe. The bipolar junction transistors Q5, Q6 are off and behave as an open circuit with extremely high impedance as there is no conduction between the emitter and the collector of Q5 and Q6. As transistors Q5 and Q6 are off, the leakage capacitance from these transistors do not significantly contribute to the conductance of the circuit and hence the overall impedance remains high. In low gain condition, Q5 and Q6 are on. Therefore, the impedance towards the emitters for Q5 and Q6 changes from high to Re in parallel with Cbe, with Cbe increasing with I_{c}. The change in impedance between maximum gain and low gain results influences the frequency response of the Gilbert cell 100, making the frequency response different across different gains, which is undesirable for ensuring signal integrity.

It is desirable to provide an electronic amplifier which reduces the influence of base-emitter capacitance (Cbe) of one or more of the transistors in the cascode stage (Q3, Q4, Q5 and Q6) of a variable gain amplifier, in order to make the frequency response of the electronic amplifier more uniform across maximum gain and low gain.

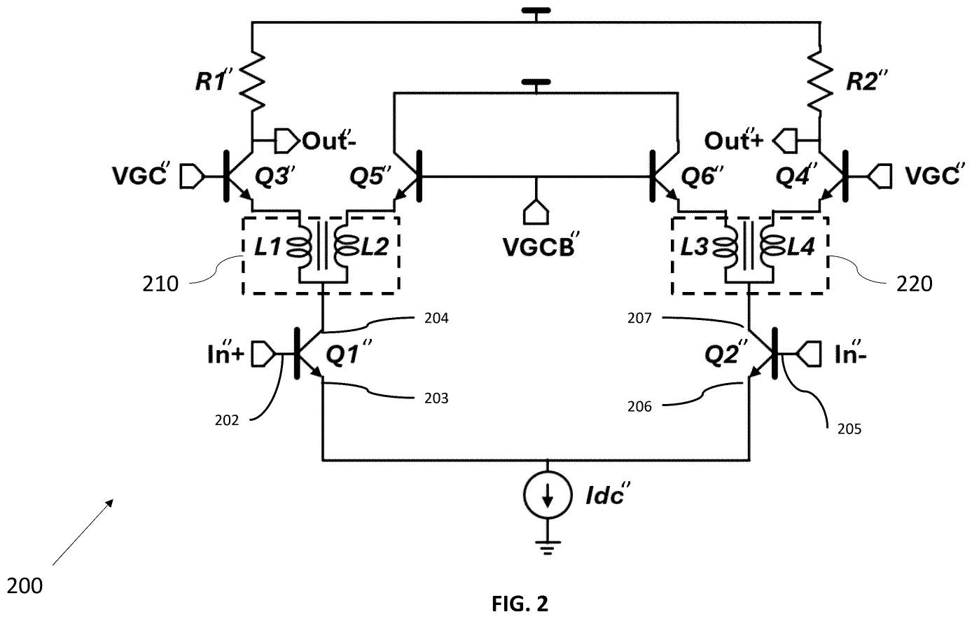

FIG. 2 is an example embodiment of an electronic amplifier 200 in accordance with the present disclosure. The electronic amplifier 200 comprises a first transistor Q1″ and a second transistor Q2″. The first transistor Q1″ comprises terminals 202, 203 and 204 which include a first terminal 202 and a second terminal 204. The second transistor Q2″ comprises terminals 205, 206 and 207 which include a third terminal 205 and a fourth terminal 207. The first transistor Q1″ and the second transistor Q2″ form a first pair of differential transistors. In this example embodiment, the first transistor Q1″ and the second transistor Q2″ are bipolar junction transistors, the first terminal 202 is the base of Q1″ and the second terminal 204 is the collector of Q1″ whilst the third terminal 205 is the base of Q2″ and the fourth terminal 207 is the collector of Q2″.

In alternative embodiments, the first transistors Q1″ and the second transistor Q2″ may be, instead, field-effect transistors (FETs), heterojunction bipolar transistor (HBT), junction FET, metal-oxide semiconductor FET, insulated gate bipolar transistor (IGBT), metal semiconductor FET, high electron mobility transistor (HEMT), Fin FET, and/or Tunnel FET in accordance with the understanding of the skilled person. The electronic amplifier 200 may, for example, a variable gain amplifier. In particular, but without limitation, it may be a Gilbert cell. In alternative embodiments, the electronic amplifier 200 may be other types of differential and single-ended Gilbert-Cell like variable gain amplifiers (VGAs).

The electronic amplifier 200 further comprises a first pair of cross coupled transistors Q3″ and Q5″ comprising a third transistor Q3″ and a fourth transistor Q5″. The third transistor Q3″ and the fourth transistor Q5″ are coupled to the first transistor Q1″ via the second terminal 204. The electronic amplifier also comprises a second pair of cross coupled transistors Q4″ and Q6″ comprising a fifth transistor Q4″ and a sixth transistor Q6″. The fifth transistor Q4″ and the sixth transistor Q6″ are coupled to the second transistor Q2″ via the fourth terminal 207. The first pair of cross coupled transistors Q3″, Q5″ and the second pair of cross coupled transistors Q4″, Q6″ form a cascode stage of the electronic amplifier 200. In the example embodiment of FIG. 2, the third transistor Q3″, fourth transistor Q5″, fifth transistor Q4″ and sixth transistor Q6″ are bipolar junction transistors. However, in alternative embodiments they may be field-effect transistors (FETs), heterojunction bipolar transistor (HBT), junction FET, metal-oxide semiconductor FET, insulated gate bipolar transistor (IGBT), metal semiconductor FET, high electron mobility transistor (HEMT), Fin FET, and/or Tunnel FET instead, in accordance with the understanding of the skilled person.

The electronic amplifier 200 comprises a load R1″ and R2″. In alternative embodiments, the load may be a resistor in parallel with a capacitor, an inductor or any combination of these circuit elements in accordance with the understanding of the skilled person.

The electronic amplifier 200 also comprises a first transformer 210 and a second transformer 220. The first transformer 210 is coupled between the second terminal 204 of the first transistor Q1″ and the first pair of cross coupled transistors Q3″ and Q5″ whilst the second transformer Q2″ is coupled between the fourth terminal 207 of the second transistor Q2″ and the second pair of cross coupled transistors Q4″ and Q6″. The first transformer 210 and the second transformer 220 are both configured to provide an impedance to the cascode stage Q3″, Q5″ and Q4″, Q6″ which is substantially constant for different amplifier gains when the electronic amplifier 200 is operated under high frequency conditions. In this example embodiment, the first transformer 210 is formed from a first pair of coupled spiral inductors L1 and L2 whilst the second transformer 220 is formed from a second pair of coupled spiral inductors L3 and L4.

In operation, the first pair of coupled spiral inductors L1 and L2 and the second pair of coupled spiral inductors L3 and L4 are orientated in such a way that the high-frequency impedance Ze towards the spiral inductor L2 (L4) at a given frequency ω is given by:

$$Ze = ω ( L 2 + k \sqrt{L 1 L 2} ( \frac{ie 3}{ie 5} ) - \frac{1}{ω Cbe 5} )$$

Where L1 (L3) and L2 (L4) are the inductors of the first (second) coupled spiral inductors, ω is one of the frequencies which the electronic amplifier 200 operates at, k is the coupling coefficient between the spirals L1 and L2 (L3 and L4), ie3 is the radio-frequency (RF) Q3″ emitter current flowing into L1, ie5 is the RF Q5″ emitter current flowing into L2 and Cbe5 is the emitter-base capacitance of Q5″. If the gain is increased, the current through Q5″ decreases and hence Cbe5 decreases and the fraction 1/(ωCbe5) increases. Therefore, the impedance due to the mutual inductance

$$( k \sqrt{L 1 L 2} ( \frac{ie 3}{ie 5} ) )$$

increases as more current flows into Q3″ and less into Q5″. Therefore, the variations in impedance Ze are reduced with increases in gain. If the gain is reduced, the current flowing into Q3″ decreases and hence Cbe3 decreases and hence the fraction 1/(ωCbe3) increases. The mutual inductance through

$$L 1 ( k \sqrt{L 1 L 2} ( \frac{ie 5}{ie 3} ) )$$

increases, thereby reducing the variations in the impedance Ze with decreases in gain.

In the context of the present disclosure, orientating the the first pair of coupled spiral inductors L1 and L2 and the second pair of coupled spiral inductors L3 and L4 means that the spiral inductors L1 and L2 (L3 and L4) are coupled such that the current flowing in one spiral L1 (L3) generates a current flowing in a first direction which is in the opposite direction to the direction of current flowing in the other spiral L2 (L4).

The first transformer 210 and the second transformer 220 provide an impedance seen from the second terminal 204 of Q1″ and the fourth terminal 207 of Q2″ towards the cascode stage that is substantially constant with gain at high frequency. This is achieved by keeping the impedances presented to the first pair of cross coupled transistors Q3″, Q5″ and the second pair of cross coupled transistors Q4″, Q6″ constant with gain.

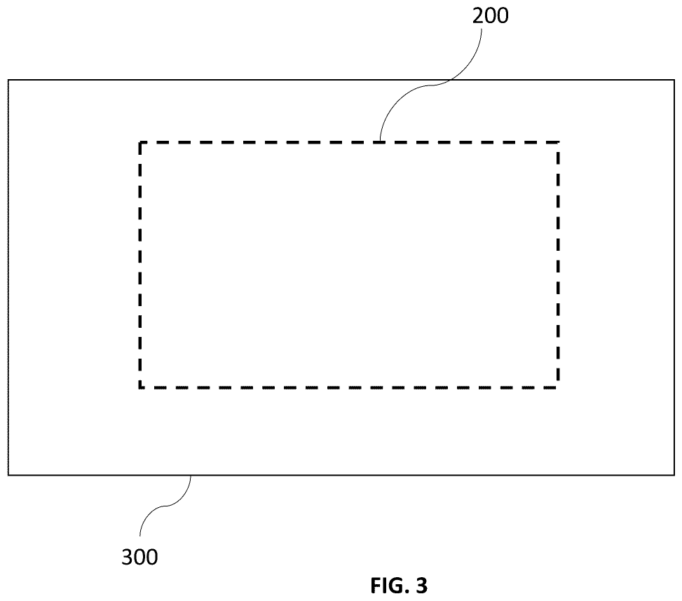

FIG. 3 is an example apparatus 300 according to the present disclosure. The apparatus 300 comprises the electronic amplifier 200 of the present disclosure. The apparatus 300 may be, for example, a communications system, an audio processing system and/or a signal conditioning system.

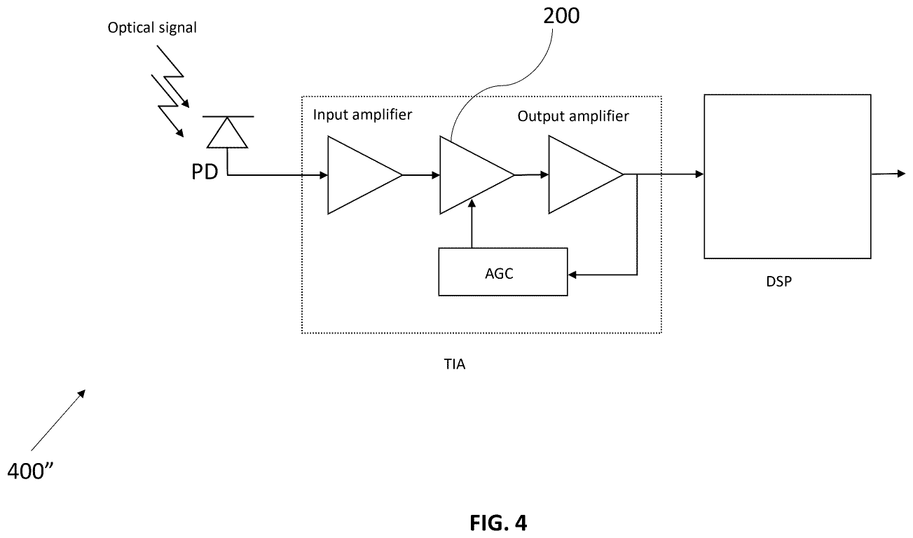

FIG. 4 is an exemplary embodiment of an apparatus 400″ comprising the electronic amplifier 200 of the present disclosure. In this exemplary embodiment, the apparatus 400″ is an optical communication system. The optical communications system 400″ comprises a transimpedance amplifier TIA, a digital signal processor DSP and a photodetector PD. The TIA comprises an input amplifier, output amplifier and the electronic amplifier 200 of the present disclosure.

In operation, the TIA amplifies a current received from the PD into a voltage for the subsequent processing by, for example, the DSP. The output of the TIA is kept constant by an automatic-gain control loop that changes the gain of the electronic amplifier 200 according to the amplitude of the TIA input current. The parameters of the DSP are calibrated such that the overall frequency response of the PD, TIA and DSP is optimal for signal integrity. If the frequency response for the TIA changes with the gain of the electronic amplifier 200, the frequency response for the overall optical communications system will not be optimal for signal integrity anymore.

It will be appreciated that the electronic amplifier of the present disclosure may be Gilbert cell for variable gain amplification systems.

A skilled person will appreciate that variations of the disclosed arrangements are possible without departing from the disclosure. Accordingly, the above description of the specific embodiments is made by way of example only and not for the purposes of limitation. It will be clear to the skilled person that minor modifications may be made without significant changes to the operation described.

In particular, it will be noted that generally the polarity of components may be reversed, that is, an npn type transistor can be alternatively implemented as a pnp type transistor, and that the disclosure is not limited to any specific polarity. Also, references to components being “coupled” with each other does not necessitate a direct physical connection; a case in point is the coupling of the second terminal 204 with the cascode stage transistor pair Q3″, Q5″ and the coupling of fourth terminal 207 with the cascode stage transistor pair Q4″, Q6″, each of which is achieved with an interposing transformer 210, 220. These components are coupled because the state of one directly affects the other. The term “connected” may also be used in a similar sense to “coupled” unless explicitly mentioned to the contrary.

1. An electronic amplifier comprising:
a first transistor comprising a first terminal and a second terminal;
a second transistor comprising a third terminal and a fourth terminal;
a first pair of cross-coupled transistors comprising a third transistor and a fourth transistor, the first pair of cross-coupled transistors connected to the second terminal;
a second pair of cross-coupled transistors the second pair of cross-coupled transistors comprising a fifth transistor and a sixth transistor, the second pair of cross-coupled transistors connected to the fourth terminal, the first and second pair of cross-coupled transistors forming a cascode stage;
a first transformer; and
a second transformer,
wherein the first transformer is coupled between the second terminal and the first pair of cross-coupled transistors and the second transformer is coupled between the fourth node and the second pair of cross-coupled transistors, such that the first transformer and the second transformer provide an impedance to the cascode stage, the impedance configured to be substantially constant for different gains when the electronic amplifier is operated with high frequency.

2. The electronic amplifier of claim 1, being a variable gain amplifier.

3. The electronic amplifier of claim 2, wherein the variable gain amplifier is a gilbert cell, a differential variable gain amplifier and/or a single-ended variable gain amplifier.

4. The electronic amplifier of claim 1, wherein the first transistor and the second transistor form a first pair of differential transistors.

5. The electronic amplifier of claim 4, wherein:
the first transistor and/or the second transistor comprise one of: a bipolar junction transistor; a field-effect transistor (FET); heterojunction bipolar transistor; junction FET; metal-oxide semiconductor FET; insulated gate bipolar transistor; metal semiconductor FET; high electron mobility transistor; Fin FET; and Tunnel FET.

6. The electronic amplifier of claim 1, wherein:
one or each of the transistors forming the first pair of cross-coupled transistors and the second pair of cross-coupled transistors comprise one of: a bipolar junction transistor; a field-effect transistor; heterojunction bipolar transistor; junction FET; metal-oxide semiconductor FET; insulated gate bipolar transistor; metal semiconductor FET; high electron mobility transistor; Fin FET; and Tunnel FET.

7. The electronic amplifier of claim 1, wherein the first transformer comprises a first pair of coupled spiral inductors and the second transformer comprises a second pair of coupled spiral inductors.

8. The electronic amplifier of claim 7, wherein the first pair of coupled spiral inductors has an orientation configured to generate a first high-frequency impedance.

9. The electronic amplifier of claim 7, wherein the second pair of coupled spiral inductors has an orientation configured to generate a second high-frequency impedance.

10. An apparatus comprising:
an electronic amplifier comprising:
a first transistor comprising a first terminal and a second terminal;
a second transistor, comprising a third terminal and a fourth terminal;
a first pair of cross-coupled transistors comprising a third transistor and a fourth transistor, the first pair of cross-coupled transistors connected to the second terminal;
a second pair of cross-coupled transistors the second pair of cross-coupled transistors comprising a fifth transistor and a sixth transistor, the second pair of cross-coupled transistors connected to the fourth terminal, the first and second pair of cross-coupled transistors forming a cascode stage;
a load;
a first transformer; and
a second transformer,
wherein the first transformer is coupled between the second terminal and the first pair of cross-coupled transistors and the second transformer is coupled between the fourth node and the second pair of cross-coupled transistors, such that the first transformer and the second transformer provide an impedance to the cascode stage, the impedance configured to be substantially constant for different gains when the electronic amplifier is operated with high frequency.

11. The apparatus of claim 10, comprising any of:
an audio processing system;
a communications system; and
a signal conditioning system.
